(19) United States
(12) Patent Application Publication
(10) Pub. No.: US 2025/0015230 A1
(43) Pub. Date: Jan. 9, 2025

(54) LIGHT EMITTING DIODE

(71) Applicant: Tianjin Sanan Optoelectronics Co., Ltd., Tianjin (CN)

(72) Inventors: Shuili YU, Tianjin (CN); Yan LI, Tianjin (CN); Taotao YIN, Tianjin (CN)

(73) Assignee: Tianjin Sanan Optoelectronics Co., Ltd., Tianjin (CN)

(21) Appl. No.: 18/759,985

(22) Filed: Jun. 30, 2024

(30) Foreign Application Priority Data
Jul. 3, 2023 (CN) 202310802196.5

(51) Int. Cl. H01L 33/20; H01L 33/30

(52) U.S. Cl. CPC H01L 33/20; H01L 33/30

(57) ABSTRACT

A light emitting diode includes: a substrate; an epitaxial structure disposed on a surface of the substrate and including a first semiconductor layer, an active layer, and a second semiconductor layer sequentially disposed in a direction away from the substrate; a first electrode disposed on the first semiconductor layer; a second electrode disposed on the second semiconductor layer; and a first trench disposed on a surface of the second semiconductor layer away from the substrate, penetrating the active layer starting from the surface of the second semiconductor layer away from the substrate, and extending to a portion of the first semiconductor layer. In the disclosure, the arrangement of the trench is beneficial to the uniform distribution of the current, so that the brightness of light emission and reliability of a chip is improved.

### CROSS-REFERENCE TO RELATED APPLICATION

This application claims the priority benefit of China application serial no. 202310802196.5, filed on Jul. 3, 2023. The entirety of the above-mentioned patent application is hereby incorporated by reference herein and made a part of this specification.

### BACKGROUND

### Technical Field

The disclosure relates to a light emitting diode.

### Description of Related Art

Light emitting diodes (LEDs for short) exhibit good optical properties such as low power consumption, high brightness, long service life, high reliability, and small area. Therefore, light emitting diodes have been widely used in various fields such as lighting, screen display, and backlight.

In recent years, requirements on optical properties and reliability of light emitting diodes have grown. For instance, greater light emitting efficiency and good initial light decay are required. In a conventional light emitting diode (FIG. 1), current can be transmitted horizontally, vertically, or in other directions, and since the current spreading paths are dispersed, the brightness of light output is affected.

### SUMMARY

The disclosure aims to solve the problems found in the related art.

An embodiment of the disclosure provides a light emitting diode including a substrate, an epitaxial structure, a first electrode, a second electrode, and a first trench. The epitaxial structure is disposed on a surface of the substrate and includes a first semiconductor layer, an active layer, and a second semiconductor layer sequentially disposed in a direction away from the substrate. The first electrode is disposed on the first semiconductor layer. The second electrode is disposed on the second semiconductor layer. The first trench is disposed on a surface of the second semiconductor layer away from the substrate, penetrates the active layer starting from the surface of the second semiconductor layer away from the substrate, and extends to a portion of the first semiconductor layer.

The beneficial technical effects brought about by the technical solutions used in this embodiment include the following. The provided first trench passes through the first semiconductor layer and the active layer, and partially extends into the second semiconductor layer, so that vertical injection of current is reduced. The current is forced to flow horizontally, current accumulation is avoided, and current uniformity and heat concentration are improved. Therefore, the brightness of light emission is improved and the initial light decay is reduced.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a cross-sectional view of a conventional light emitting diode.

FIG. 2 is a cross-sectional view of a light emitting diode provided in Embodiment one of the disclosure.

FIG. 3 is a cross-sectional view of a light emitting diode provided in Embodiment two of the disclosure.

FIG. 4 is a cross-sectional view of a conventional large-sized light emitting diode.

FIG. 5 is a cross-sectional view of a light emitting diode provided in Embodiment three of the disclosure.

FIG. 6 is a top view of the light emitting diode provided in Embodiment three of the disclosure.

FIG. 7 is a cross-sectional view of a light emitting diode provided in Embodiment four of the disclosure.

FIG. 8 shows optical parameters of a conventional light emitting diode, the light emitting diode of Embodiment three of the disclosure, and the light emitting diode of Embodiment four of the disclosure.

### DESCRIPTION OF THE EMBODIMENTS

The implementation of the disclosure is described in detail below with reference to the accompanying drawings and embodiments. Before describing the disclosure, it should be understood that the disclosure can be implemented in many different forms and therefore the disclosure is not limited to the specific embodiments described below.

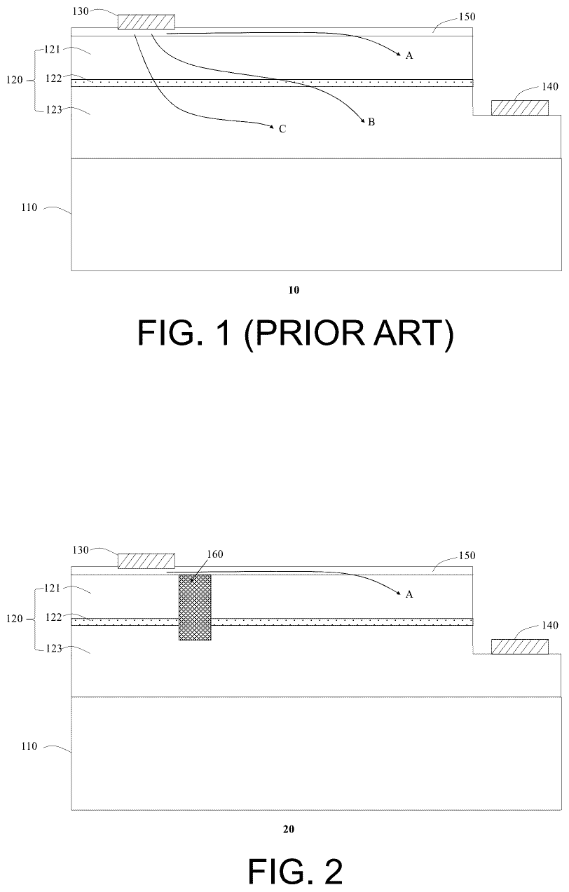

In a conventional horizontal light emitting diode (LED) structure 10 as shown in FIG. 1, current expansion is generally divided into three paths: A, B, and C. Since the current has the shortest transmission path and path C is the shortest, the current is most easily transmitted through path C, so more current is gathered in a vertical direction, and less current flows through the horizontal paths A and B. This makes it difficult for the current to spread and the current in an epitaxial layer is uneven. The phenomenon of vertical current injection affects the brightness of a light emitting surface on the one hand and easily causes current accumulation on the other hand, resulting in a large amount of heat being dissipated. This causes low reliability issues, such as initial light decay of a chip.

In view of the above defects, the disclosure provides a light emitting diode, which is described in detail through the following embodiments.

### Embodiment One

This embodiment provides a light emitting diode 20, and FIG. 2 is a cross-sectional view of this embodiment. The light emitting diode 20 includes an epitaxial structure 120, and the epitaxial structure 120 includes a second semiconductor layer 121, an active layer 122, and a first semiconductor layer 123, and is formed on a substrate 110. In the light emitting diode with a horizontal structure, in order to allow the lateral spreading of the injected current to be enhanced, in this embodiment, an electron beam evaporation device is used to evaporate a layer of ITO transparent conductive film on an upper surface of the second semiconductor layer 121 as a transparent conductive layer 150. A second electrode 130 having a same polarity as the second semiconductor layer 121 is disposed on a surface of the second semiconductor layer 121, and a first electrode 140 having a same polarity as the first semiconductor layer is formed on a surface of the first semiconductor layer 123.

As shown in FIG. 2, a first trench 160 disposed on a surface of the second semiconductor layer 121 away from the substrate 110, extends downward, passes through the active layer 122, and extends to a portion of the first semiconductor layer 123. The first trench 160 may be obtained by dry etching, such as inductively coupled plasma-reactive ion etching (ICP-RIE), or by solution wet etching. The trench may also be formed by, for example, laser processing. In this embodiment, in order to ensure accurate formation of the first trench 160, a dry etching method is used. The specific method is as follows: a photomask is used to pattern and protect other portions of the second semiconductor layer 121, and ICP dry etching is used to expose the second semiconductor layer 121 to form the first trench 160. The first trench 160 is filled with an insulating light-transmitting material, such as silicon dioxide, silicon nitride, etc., to prevent problems such as leakage and short circuit from occurring.

The first trench 160 is disposed on the surface of the second semiconductor layer 121 away from the substrate 110 and is beside the second electrode 130. Preferably, a distance between the first trench 160 and the second electrode 130 is greater than 10 micrometers and less than 30 micrometers. In this embodiment, the distance between the first trench 160 and the second electrode 130 is greater than 15 micrometers and less than 25 micrometers. This helps improve the vertical injection of current under the second electrode 130. If the distance between the first trench 160 and the second electrode 130 is less than 10 micrometers, the second electrode 130 may be uneven, causing problems in subsequent wire bonding. Further, an ohmic contact of the second electrode 130 may also be affected. On the contrary, if the distance between the first trench 160 and the second electrode 130 is greater than 30 micrometers, the improvement on vertical current injection under the second electrode 130 is not obvious and the current accumulation problem still exists, resulting in dim brightness of light emission.

The technical effect of the disclosure is closely related to a depth of the first trench 160. The depth of the first trench 160 should at least pass through the active layer 122, and with this design, the current may be less injected in the vertical direction and more conducted in a horizontal direction. Preferably, the first trench 160 extends into 5% to 20% of the first semiconductor layer 123, or extends into 20% to 95% of the first semiconductor layer 123. If the depth of the first trench 160 is excessively shallow, for example, the depth extending to the first semiconductor layer 123 is less than 5% of the first semiconductor layer 123, the current spreading effect is not obvious, the vertically injected current is still accumulated, and the brightness of light emission is low. On the contrary, if the depth of the first trench 160 is excessively large and extends beyond 95% of the first semiconductor layer 123, leakage risk may easily occur. In this embodiment, the first trench 160 penetrates the active layer 122 and extends to 5% to 20% of the second semiconductor layer 121.

In Embodiment one, by arrangement of the first trench 160, part of the current below the second electrode 130 is blocked, the vertical injection of current is reduced, and the current is forced to be transmitted in the horizontal direction, so that current flows to the entire epitaxial layer as much as possible, and the uniformity of current distribution is thus enhanced. In this way, the brightness of light emission of the light emitting diode is improved, the phenomenon of current accumulation and heat generation is improved, and the reliability of the chip is enhanced.

### Embodiment Two

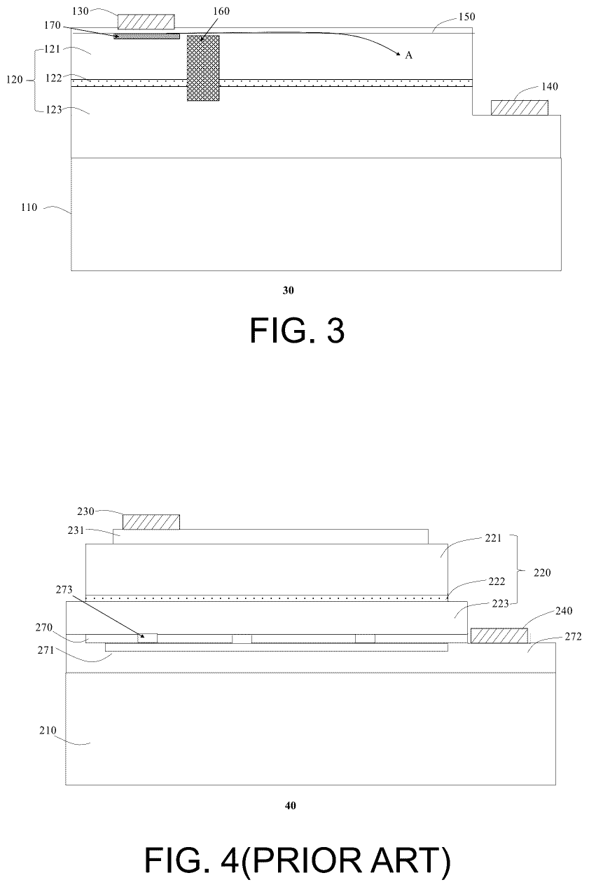

Embodiment two provides another light emitting diode 30 with a horizontal structure, as shown in FIG. 3. On the basis of Embodiment one, a second trench 170 is further provided, which is located on the surface of the second semiconductor layer 121 away from the substrate 110. An orthographic projection of the second electrode 130 on the substrate 110 is located within an orthographic projection of the second trench 170 on the substrate 110. The second trench 170 may be formed by photomask and wet etching and may also be formed by dry etching, such as inductively coupled plasma-reactive ion etching (ICP-RIE). The second trench 170 may also be processed by laser. In this embodiment, the second trench 170 is formed by using a photomask and a solution wet etching method. Preferably, a depth of the second trench 170 is greater than 500 angstroms and less than 900 angstroms. If the depth of the second trench 170 is excessively shallow, less than 500 angstroms, the vertical current blocking effect is not obvious, and the brightness of light emission and the reliability of the chip cannot be effectively enhanced. If the depth of the second trench 170 is excessively deep, greater than 900 angstroms, a height of the second electrode 130 is affected, causing the second electrode 130 to be uneven, and the subsequent wire bonding may be affected.

The second trench 170 is filled with an insulating light-transmitting material, such as silicon dioxide, nitride oxide, etc.

In Embodiment two, in addition to the first trench 160, the second trench 170 is further provided under the second electrode. In this way, the current under the second electrode is further blocked, and the vertical injection of current is reduced. Most of the current is transmitted along the horizontal path A, so current uniformity is further enhanced, the brightness of light emission of the light emitting diode is significantly improved, the phenomenon of current accumulation and heat generation is improved, the reliability of the chip is enhanced, and the initial light decay is optimized.

### Embodiment Three

Large-sized light emitting diodes usually provide higher power and require better current uniformity. The disclosure is suitable for high-power light emitting diode chips and can be widely used in projection, stage lights, etc.

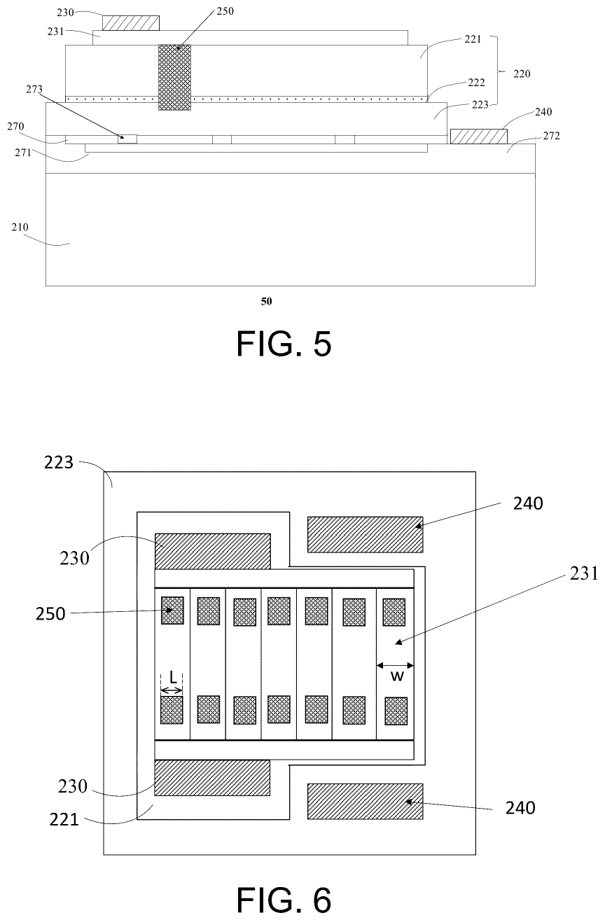

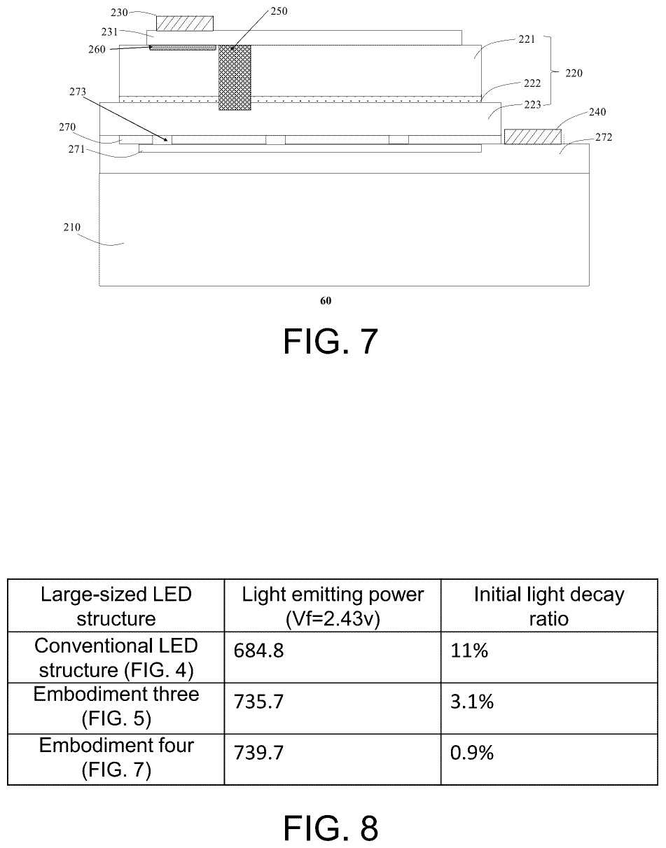

FIG. 4 is a conventional large-sized light emitting diode 40.

The light emitting diode has a large current density. In a conventional large-sized structure, due to the dispersed current transmission paths, the current distribution uniformity is poor, the brightness of light output is low, and an initial light decay ratio is high. The reliability of the light emitting diode is low.

Embodiment three of the disclosure provides a high-power light emitting diode 50, as shown in the cross-sectional schematic view of FIG. 5. The following structures are included: a substrate 210, an epitaxial structure 220, a second semiconductor layer 221, an active layer 222, a first semiconductor layer 223, a second electrode 230, an extended electrode 231, a first electrode 240, a first trench 250, a current blocking layer 270, a reflective layer 271, a bonding layer 272, and a via 273.

L is a width of the first trench (with reference to FIG. 6), and W is a width of the extended electrode (with reference to FIG. 6).

Each structure is described in detail in the following paragraphs.

The substrate 210 is a semiconductor substrate, such as sapphire, silicon carbide, aluminum nitride, etc. In this embodiment, a material of the substrate 210 is aluminum nitride, and the substrate 210 has a thickness of 180 um±25 um.

The epitaxial structure 220 includes the first semiconductor layer 223, the second semiconductor layer 221, and the active layer 222 between the first semiconductor layer 223 and the second semiconductor layer 221. The first semiconductor layer 223 and the second semiconductor layer 221 may be implemented as material layers providing electrons or holes through n-type doping or p-type doping. The N-type semiconductor layer may be doped with an n-type dopant such as Si, Ge, or Sn, and the P-type semiconductor layer may be doped with a p-type dopant such as Mg, Zn, Ca, Sr, or Ba.

The second semiconductor layer 221, the active layer 222, and the first semiconductor layer 223 may be specifically made of materials such as aluminum gallium indium nitride, gallium phosphide, gallium nitride, aluminum gallium nitride, aluminum indium phosphide, aluminum gallium indium phosphide, gallium arsenide, or aluminum gallium arsenic. The active layer 222 may be a single quantum well or a periodic structure of multiple quantum wells. By adjusting a composition ratio of the semiconductor materials in the active layer 222, it is expected that light of different wavelengths may be radiated. In this embodiment, the material of the active layer 222 preferably is aluminum gallium indium phosphide or aluminum gallium arsenic. The active layer may radiate red light or infrared light.

The light emitting diode of Embodiment three further includes the first trench 250. The first trench 250 is disposed on a surface of the second semiconductor layer 221 away from the substrate and is beside the second electrode 230. Preferably, a distance between the first trench 250 and the second electrode 230 is greater than 10 micrometers and less than 30 micrometers. In this embodiment, the distance between the first trench 250 and the second electrode 230 is greater than 15 micrometers and less than 25 micrometers. This helps improve the vertical injection of current under the second electrode 230. If the distance between the first trench 250 and the second electrode 230 is less than 10 micrometers, the second electrode 230 may be uneven, causing problems in subsequent wire bonding. Further, an ohmic contact of the second electrode 230 may also be affected. On the contrary, if the distance between the first trench 250 and the second electrode 230 is greater than 30 micrometers, the improvement on vertical current injection under the second electrode 230 is not obvious and the current accumulation problem still exists, resulting in dim brightness of light emission.

The first trench 250 penetrates the active layer 222 starting from the surface of the second semiconductor layer 221 away from the substrate 210 and at least partially extends to the first semiconductor layer 223. Preferably, the first trench 250 extends to 5% to 20% of the first semiconductor layer 223 or extends to 20% to 95% of the first semiconductor layer 223. If a depth of the first trench 250 is excessively shallow and the depth of the first trench 250 penetrating the first semiconductor layer 223 is less than 5% of the first semiconductor layer 223, the phenomenon of vertical current injection cannot be effectively improved. On the contrary, if the depth of the first trench 250 is excessively large, exceeding 95% of the first semiconductor layer 223, leakage risk may easily occur. The first trench 250 is formed by dry etching and filled with an insulating light-transmitting material, such as silicon dioxide, silicon nitride, etc., to prevent problems such as leakage and short circuit from occurring.

In Embodiment three, the current blocking layer 270 is disposed under the first semiconductor layer 223 and a material thereof is SiO₂. Current easily accumulating under the electrodes of the light emitting diode causes uneven light emission and excessively high local temperature, and the reliability of the light emitting diode is thus affected. The arrangement of the current blocking layer 270 is beneficial to current spreading, so that the current is evenly distributed and the brightness of the chip is improved. The current blocking layer 270 has the via 273 therein. The via is formed by photomask and wet etching and is filled with a conductive material such as evaporated Au and AuGeNi. An ohmic contact may be formed with the epitaxial structure 220 through the via 273.

The reflective layer 271 is disposed below the current blocking layer 270, and a material thereof may be one or more of Au, Ag, Pt, and Ti. The arrangement of the reflective layer 271 is beneficial to improving the reflection efficiency, reducing the light absorption of the upper extended electrode 231, and increasing the light extraction efficiency.

The bonding layer 272 is disposed between the substrate 210 and the epitaxial structure 220, and the epitaxial structure 220 is connected to the substrate 210 through the bonding layer 272. Both the current blocking layer 270 and the reflective layer 271 are completely covered by the bonding layer 272. A material of the bonding layer 272 may be one or more of Ti, Pt, and Au.

Embodiment three further includes the first electrode 240 and the second electrode 230, and both of which are made of metal materials in this embodiment.

The second electrode 230 is disposed on the second semiconductor layer 221, and the extended electrode 231 is disposed below the second electrode 230. The arrangement of the extended electrode 231 is helpful for current spreading and reduces the current accumulation of the second electrode 230.

The epitaxial structure 240 is dry-etched, starting from the surface of the second semiconductor layer away from the substrate and stopping after the active layer 222 is etched. The first semiconductor layer 223 is exposed to form a first mesa, which is convenient for subsequent chip segmentation.

The first semiconductor layer 223 is etched until the bonding layer 272 is exposed to form a second mesa, and the first electrode 240 is disposed on this mesa.

Compared to the conventional large-sized light emitting diode shown in FIG. 4, this embodiment is characterized in that the first trench 250 is provided, so that the vertical current injection under the second electrode is effectively blocked. On the one hand, the current is forced to transmit in the horizontal direction, so the uniformity of current is improved, and the brightness of light emission of the light emitting diode is enhanced. On the other hand, the current accumulation is reduced, the problem of overheating of the light emitting diode is improved, the reliability of the light emitting diode is enhanced, and the initial light decay of the chip is improved.

FIG. 6 is a top view of the light emitting diode 50 in Embodiment three. This embodiment adopts a double-sided pad structure, with two pairs of first electrodes 240 and second electrodes 230, and the first trenches 250 are disposed at both ends of the extended electrodes 231. In this embodiment, the width L of the first trench 250 is less than the width W of the extended electrode 231.

### Embodiment Four

Another large-sized light emitting diode 60 is provided based on Embodiment four of the disclosure, as shown in FIG. 7. On the basis of Embodiment three in FIG. 5, a second trench 260 is further provided, which is located on the surface of the second semiconductor layer 221 away from the substrate 210. An orthographic projection of the second electrode 230 on the substrate 210 is located within an orthographic projection of the second trench 260 on the substrate 210. The second trench may be formed by wet etching with a photomask or may be formed by dry etching and laser processing. In this embodiment, the second trench 260 is formed by using a photomask and wet etching. Preferably, a depth of the second trench 260 is greater than 500 angstroms and less than 900 angstroms. If the depth of the second trench 260 is excessively shallow, less than 500 angstroms, the vertical current blocking effect is not obvious, and the brightness of light emission and the reliability of the chip cannot be effectively enhanced. If the depth of the second trench 260 is excessively deep, greater than 900 angstroms, a height of the second electrode 230 is affected, and the subsequent wire bonding may be affected.

The second trench 260 is filled with an insulating light-transmitting material, such as silicon oxide, silicon nitride, nitrogen oxide, etc. In this way, problems such as leakage are prevented from occurring, and the reliability of the light emitting diode is enhanced.

In Embodiment four, in addition to the first trench 250, the second trench 260 is further provided under the second electrode 230. In this way, the current accumulation under the second electrode 230 is further blocked, and the vertical injection of current is reduced. In this way, most of the current is forced to be transmitted along the horizontal path and spreads throughout the entire epitaxial structure. Therefore, current uniformity is further enhanced, the brightness of light emission is significantly improved, the phenomenon of accumulation and heat generation is improved, the reliability of the light emitting diode is enhanced, and the initial light decay is optimized.

FIG. 8 shows a comparison of photoelectric parameters of the conventional large-sized light emitting diode of FIG. 4, the light emitting diode provided in Embodiment three of FIG. 5 and the light emitting diode provided in Embodiment four of FIG. 7.

FIG. 8 mainly compares the light emitting power and the initial light decay ratio of three light emitting diodes.

In terms of light emitting power, the brightness of light emission may be improved through the embodiments of the disclosure. Compared to the conventional large-sized light emitting diode in FIG. 4, the light emitting diode in Embodiment three of FIG. 5, i.e., the light emitting diode provided with the first trench 250, has a brightness increased by 5%. In Embodiment four shown in FIG. 7, the first trench 250 and the second trench 260 are provided together, so the brightness of light emission is further optimized.

In terms of the initial light decay ratio, the initial light decay ratio of the light emitting diode may be further improved through the embodiments of the disclosure. Compared to the initial light decay ratio of 11% of the conventional large-sized light emitting diode shown in FIG. 4, Embodiment three shown in FIG. 5, i.e., the light emitting diode provided with the first trench 250, may allow the initial light decay ratio to be decreased to 3.1%. In Embodiment four shown in FIG. 7, the first trench 250 and the second trench 260 are provided together, so the initial light decay ratio of the light emitting diode may further be reduced to 0.9%.

It can be seen from the above technical solutions that in the light emitting diode provided by the disclosure, the problems of low brightness of light emission and large initial light decay ratio found in a conventional light emitting diode are improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A light emitting diode, comprising:
a substrate;
an epitaxial structure disposed on a surface of the substrate and comprising a first semiconductor layer, an active layer, and a second semiconductor layer sequentially disposed in a direction away from the substrate;
a first electrode disposed on the first semiconductor layer;
a second electrode disposed on the second semiconductor layer; and
a first trench disposed on a surface of the second semiconductor layer away from the substrate, penetrating the active layer starting from the surface of the second semiconductor layer away from the substrate, and extending to a portion of the first semiconductor layer.

2. The light emitting diode according to claim 1, wherein
the first trench extends into 5% to 20% of the first semiconductor layer, or the first trench extends into 20% to 95% of the first semiconductor layer.

3. The light emitting diode according to claim 1, wherein
the first trench is filled with an insulating material.

4. The light emitting diode according to claim 1, wherein
a distance between the first trench and the second electrode is greater than 10 micrometers and less than 30 micrometers.

5. The light emitting diode according to claim 1, further comprising:
a second trench located on the surface of the second semiconductor layer away from the substrate.

6. The light emitting diode according to claim 5, wherein
an orthographic projection of the second electrode on the substrate is located within an orthographic projection of the second trench on the substrate.

7. The light emitting diode according to claim 5, wherein
a depth of the second trench is greater than 500 angstroms and less than 900 angstroms.

8. The light emitting diode according to claim 5, wherein
the second trench is filled with an insulating material.

9. The light emitting diode according to claim 1, wherein
a material of the active layer is aluminum gallium indium phosphide or aluminum gallium arsenic.

10. The light emitting diode according to claim 1, further comprising:
a transparent conductive layer disposed between the second electrode and the second semiconductor layer.

11. The light emitting diode according to claim 1, further comprising:
an extended electrode disposed below the second electrode.

12. The light emitting diode according to claim 1, further comprising:
a current blocking layer disposed below the first semiconductor layer.

13. The light emitting diode according to claim 12, further comprising:
a reflective layer disposed below the current blocking layer.

14. The light emitting diode according to claim 12, further comprising:
a bonding layer disposed between the substrate and the epitaxial structure.

15. The light emitting diode according to claim 12, wherein
the current blocking layer has a via, and the via is filled with a conductive material.
